(19) United States
(12) Patent Application Publication
(10) Pub. No.: US 2006/0018352 A1
(43) Pub. Date: Jan. 26, 2006

(54) Ridge-type semiconductor laser and method of fabricating the same

(75) Inventors: Jung Ho Song, Seoul (KR); Kisoo Kim, Jeollabuk-do (KR); Yongsoon Baek, Daejeon-city (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Electronics and Telecommunications Research Institute

(21) Appl. No.: 11/008,064

(22) Filed: Dec. 8, 2004

(30) Foreign Application Priority Data
Jul. 20, 2004 (JP) 2004-56417

(51) Int. Cl. H01S 5/00

(52) U.S. Cl. 372/46.01

(57) ABSTRACT

A ridge-type semiconductor laser is provided. The ridge-type semiconductor laser includes a pattern for a current inflow path control formed on an active layer and having an opening thereinside controlling a current inflow path with a width W1, and a ridge formed on the pattern for a current inflow path control, with a width W2 greater than W1 and burying the opening with a width W1 and controlling an optical mode. The ridge-type semiconductor laser improves the characteristics of a laser by separately controlling the extent that current is spread in the space, and the extent that optical mode is spread in the space, to maximize the coincidence of the respective space distributions of the current and the optical mode.

### BACKGROUND OF THE INVENTION

This application claims the priority of Korean Patent Application No. 2004-56417, filed on Jul. 20, 2004, in the Korean Intellectual Property Office, the disclosure of which is incorporated herein in its entirety by reference.

1. Field of the Invention

The present invention relates to a semiconductor laser and a fabrication method thereof, and more particularly, to a ridge-type semiconductor laser and a method of fabricating the same.

2. Description of the Related Art

Generally, a ridge-type semiconductor laser has advantages of simple fabrication processes and a high production yield because it can be fabricated without complicated etch process and regrowth process in comparison with a buried heterostructure (BH) laser.

FIG. 1 is a sectional view illustrating an example of a conventional ridge-type semiconductor laser.

In specific, an InGaAsP active layer 3 and a p-InP layer 5 are formed on an n-InP substrate 1. An InGaAsP etch stop layer 7 is formed on the p-InP layer 5, and a p-InP ridge 9 is formed on the InGaAsP etch stop layer 7.

The p-InP ridge 9 is formed using the InGaAsP etch stop layer 7 during the formation process. An InGaAs electrode contact layer 11 is formed on the p-InP ridge 9, and a passivation layer 13 is formed on both sidewalls of the p-InP ridge 9. An electrode metal layer 15 is formed on the InGaAs electrode contact layer 11 and the passivation layer 13.

In the ridge-type semiconductor laser, the optical mode is determined by the p-InP ridge 9. Particularly, the dimension of the optical mode in the lateral direction is determined by the width of the ridge. In the ridge-type semiconductor laser, the electrode metal layer 15 is applied with an anode, and the n-InP substrate 1 is applied with a cathode. Thus, the holes injected by the InGaAs electrode contact layer 11 go into the InGaAsP active layer 3 along the p-InP ridge 9. Further, the electrons coming into the InGaAsP active layer 3 along the n-InP substrate 1 are recombined, so as to flow an electric current. When the stimulated emission by light is increased with recombination, a laser starts lasing. Since the diffusion length of electrons is greater than that of holes, the width of the active region in the InGaAsP active layer 3 is determined by the diffusion of holes. Thus, the width of the active region in the InGaAsP active layer 3 is determined by the width W of the ridge.

However, in the ridge-type semiconductor laser of FIG. 1, a significant amount of current may be lost, not serving to produce light, because the extent that current is spread along the InGaAsP active layer 3 is much greater than the dimension of the optical mode. Therefore, the ridge-type semiconductor laser of FIG. 1 has threshold currents higher than the BH laser.

FIG. 2 is a sectional view illustrating an example of a conventional ridge-type semiconductor laser. In specific, an n-GaN layer 23 is formed on a substrate 21, and an active layer 25 is formed on the n-GaN layer 23. A p-AlGaN/GaN layer 27 and a p-AlGaN/GaN ridge 29 are sequentially formed on the active layer 25. Depletion layers 31 are formed on the active layer 25 on both sides of the p-AlGaN/GaN layer 27.

A p-GaN electrode contact layer 33 is formed on the p-AlGaN/GaN ridge 29. Passivation layers 35 are respectively formed on both sidewalls and the upper surface of the p-AlGaN/GaN ridge 29, and on the upper surface of the depletion layer 31, to expose a partial surface of the p-GaN electrode contact layer 33, and a partial surface of the depletion layer 31. A current inflow electrode 37 is formed on a partial surface of the exposed p-GaN electrode contact layer 33, and an electrode for current inflow path control 39 is formed on a partial surface of the exposed depletion layer 31.

The ridge-type semiconductor laser of FIG. 2 includes the electrode for current inflow path control 39 for reducing a width that current is spread in order to lower the threshold current of a ridge-type semiconductor laser. That is, the electrode for current inflow path control 39 controls the width of the path through which a current flows on the bottoms of the both sides of the p-AlGaN/GaN ridge 29. The electrode for current inflow path control 39 makes current flow just with a constant width when a reverse direction of voltage is applied to form the depletion layer 31 as shown in FIG. 2. By controlling the reverse voltage applied to the electrode for current inflow path control 39 to change the thickness of the depletion layer 31, the width of the path through which current flows can be controlled. Therefore, the ridge-type semiconductor laser of FIG. 2 can lase just with one optical mode even in the case that a ridge has a great width, by narrowing the current inflow path width, and lower a threshold current by reducing the current spreading in the active layer 25.

However, the ridge-type semiconductor laser of FIG. 2 can be applied to a GaN group of a semiconductor laser which is difficult to make the width of the ridge I less than a few micron, but may have a disadvantage to be applied to an InP group of a semiconductor laser having a few micron of a ridge width because two more electrodes must be formed very close to each other in the fabrication process.

Further, in the ridge-type semiconductor laser of FIG. 2, the electrode for current inflow path control 39 determines the width of the path through which current flows, and concurrently, greatly affects the optical mode. Therefore, in the ridge-type semiconductor laser of FIG. 2, the extent the extent that current is spread in the space, and the extent that optical mode is spread in the space cannot be controlled separately, which is disadvantageous.

### SUMMARY OF THE INVENTION

The present invention provides a ridge-type semiconductor laser for improving the characteristics of a laser by separately controlling the extent the extent that current is spread in the space, and the extent that optical mode is spread in the space, to maximize the coincidence of the respective space distributions of current and optical mode.

The present invention provides a method of fabricating a ridge-type semiconductor laser for separately controlling the extent that current is spread in the space, and the extent that optical mode is spread in the space.

According to an aspect of the present invention, there is provided a ridge-type semiconductor laser including an active layer formed on a substrate, and a pattern for a current inflow path control formed on the active layer and having an opening thereinside controlling a current inflow path with a width W1.

The ridge-type semiconductor laser also includes a ridge formed on the pattern for a current inflow path control with a width W2 greater than W1, and burying the opening with a width W1 and controlling an optical mode. An electrode contact layer pattern is formed on the ridge, and a passivation layer is formed on both sidewalls of the ridge and on the active layer. An electrode metal layer is formed on the electrode contact layer pattern and the passivation layer.

Preferably, the substrate may be formed of an n-substrate, the ridge may be formed of a p-semiconductor layer, and the pattern for a current inflow path control may be formed of an n-semiconductor layer. The ridge may be formed of a p-InP layer, and the pattern for a current inflow path control may be formed of an n-InP layer. The active layer may be formed of an InGaAsP layer. The active layer under the ridge may be formed of a p-InGaAsP layer, and the active layer other than that may be formed of an n-InGaAsP layer.

According to another aspect of the present invention, there is provided a method of fabricating a ridge-type semiconductor laser, which includes forming an active layer on an n-substrate, and forming an etch stop layer on the active layer. After forming an n-semiconductor layer on the etch stop layer, the n-semiconductor layer and the etch stop layer are patterned, thereby forming an n-semiconductor layer pattern having an opening thereinside with a width W1, and an etch-stop layer pattern.

After forming a p-semiconductor layer on the n-semiconductor layer pattern, burying the opening, an electrode contact layer is formed on the p-semiconductor layer. The electrode contact layer, the p-semiconductor layer, and the n-semiconductor layer are patterned, thereby forming an electrode contact layer pattern, a ridge with a width W2 greater than the width W1, and a pattern for a current inflow path width control having an opening thereinside with a width W1. After forming a passivation layer on both sidewalls of the ridge and the etch stop layer pattern, an electrode metal layer is formed on the electrode contact layer pattern and the passivation layer.

As described above, the ridge-type semiconductor laser of the present invention improves the characteristics of a laser by separately controlling the extent that current is spread in the space, and the extent that optical mode is spread in the space, and maximably coinciding the respective space distributions of current and optical mode.

### BRIEF DESCRIPTION OF THE DRAWINGS

The above and other features and advantages of the present invention will become more apparent by describing in detail exemplary embodiments thereof with reference to the attached drawings in which:

FIGS. 1 and 2 are sectional views of a conventional ridge-type semiconductor laser;

FIGS. 3 through 5 are graphs explaining the theory of a ridge-type semiconductor laser of the present invention;

FIG. 6 is a sectional view of a ridge-type semiconductor laser according to one embodiment of the present invention;

FIG. 7 is a sectional view of a ridge-type semiconductor laser according to another embodiment of the present invention; and

FIGS. 8 through 11 are sectional views illustrating a method of fabricating the ridge-type semiconductor laser of FIG. 6.

### DETAILED DESCRIPTION OF THE INVENTION

The present invention will now be described more fully hereinafter with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. Like numbers refer to like elements throughout the specification.

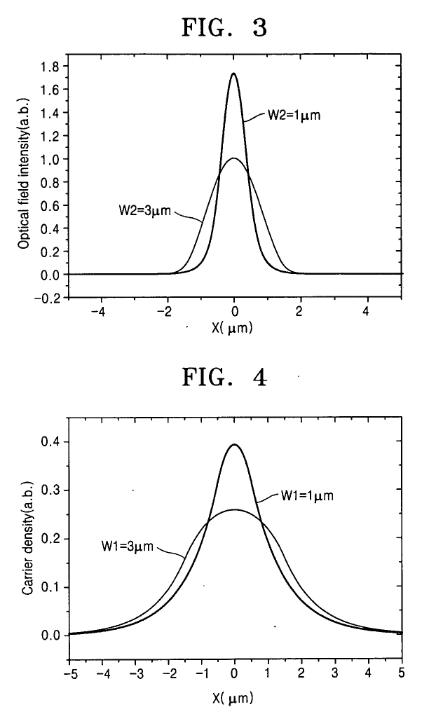

FIGS. 3 through 5 are graphs explaining the theory of a ridge-type semiconductor laser of the present invention.

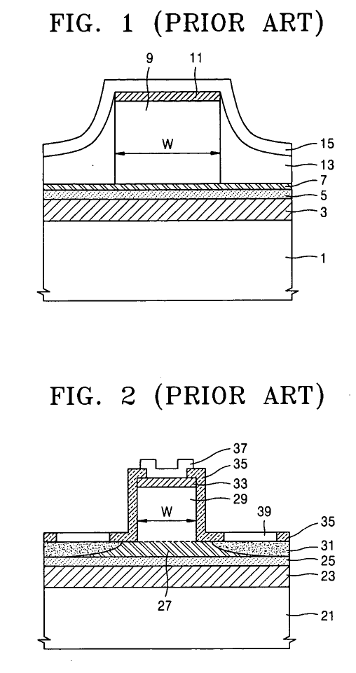

In specific, G. J. Letel, et. al. disclosed an extent of the current spread in the active layer of the conventional ridge-type semiconductor laser of FIG. 1 in the paper entitled “Determination of active-region leakage currents in ridge-waveguide strained-layer quantum-well lasers by varying the ridge width” (IEEE J. of Quantum Electronics, vol. 34, No. 3, pp. 512-518, 1998). That is, the space distribution of holes as carriers may be presented by following Formulas, and it can be respectively presented as Formulas 1 and 2 in the outside and the inside of the ridge width determining a current inflow path. In the conventional technology, a current inflow path width and a waveguide mode width can be determined by a ridge width concurrently, but according to the present invention, the current inflow path width W1 is different from the ridge width W2, and the current inflow width used in the Formulas 1 and 2 is the current inflow path width W1, not the ridge width.
p(x)=[(Jin τ)/(q d)]exp(−|x|/LD) sin h(W1/2LD) |x|>(W1/2) <Formula 1>
p(x)=[(Jin·τ)/(q·d)][1−exp(−W1/2LD)·cos h(x/2LD)]|x|<(W1/2) <Formula 2>

Herein, p(x) is a hole density profile in the lateral direction, Jin is an injection current density, d is a thickness of an active layer, q is a charge amount of electrons, τ is a life time of holes, and LD is a diffusion length of holes.

Further,. an average recombination current density, J′ in the inside of the ridge width W2 where the optical intensity of the optical mode is high may be presented by Formula 3 as follows.

$${J}^{′} = \frac{dq}{W2} {\int }_{\frac{- w2}{2}}^{\frac{w2}{2}} \frac{p ( X )}{τ} ⅆ x \qquad < Formula 3 >$$

As described above, W1 is a current inflow path width in the inner width of the ridge, and W2 is a ridge width determining a dimension of the optical mode in the outer width of the ridge.

FIG. 3 illustrates the space distribution of the optical intensity of the optical mode in accordance with the ridge width W2. FIG. 4 illustrates the space distribution of the carrier density of holes in accordance with the current inflow path width W1. The “LD” is 1 μm. As shown in FIGS. 3 and 4, the space distribution of the holes is much wider than the space distribution of the optical intensity of the optical mode with a same width.

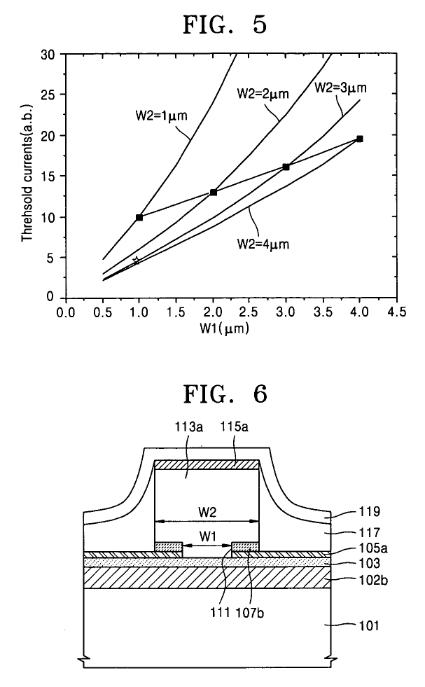

From Formulas 1 and 2 presenting the space distribution of holes, and Formula 3, J′, a ratio of the current useful in the laser relative to inflow current can be calculated. Calculation results based on these formulas with W2 and W1 are presented in FIG. 5.

The solid lines of FIG. 5 present threshold currents in accordance with the current inflow path width W1 with respectively given ridge widths W2. The line connecting solid square marks presents the structure of the ridge-type semiconductor laser when W1 and W2 are identical. It can be known that the threshold current is low with the ridge width narrower. In FIG. 5, the star mark presents the case that the ridge width W2 is 3 μm, and the current inflow path width W1 is 1 μm, and the threshold current is reduced by 50% or more than that of the case that W1 and W2 are identical as 1 μm. Therefore, the ridge-type semiconductor device of the present invention is structured such that the ridge width W2 is 3 μm, and the current inflow path width W1 is 1 μm smaller than W2.

FIG. 6 is a sectional view of a ridge-type semiconductor laser according to one embodiment of the present invention.

In specific, an active layer 102 and the p-clad layer 103 are sequentially formed on the n-substrate 101. The n-substrate 101 is formed of an n-substrate, for example, n-InP substrate, and the active layer 102 is formed of an InGaAsP layer of a quantum well structure, or an InGaAsP layer of a non-quantum well structure, and the p-clad layer 103 is formed of a p-semiconductor layer, for example, p-InP layer. The p-clad layer 103 is formed with a thickness of 0.1 μm. The p-clad layer 103 may not be formed if unnecessary.

An etch stop layer 105a having an opening thereinside with a width W1 is formed on the p-clad layer 103. The etch stop layer pattern 105a is formed of an InGaAsP layer. The etch stop layer 105 is formed with a thickness of 300′.

A pattern for a current inflow path width control 107b is formed on the etch stop layer pattern 105a, having an opening 111 with a width equal to the W1, and partially exposing the surface of the etch stop layer pattern 105a. Using the opening 111 with the width W1 formed inside the pattern for a current inflow path width control 107b, a current inflow path can be controlled. That is, the pattern for a current inflow path width control 107b functions to stop the flow of holes and not to allow a current to pass through. The pattern for a current inflow path width control 107b is formed of an n-semiconductor layer, for example, an n-InP layer. The pattern for a current inflow path width control 107b is formed with a thickness of 0.2 μm.

A ridge 113a is formed on the etch stop layer pattern 105a and the pattern for a current inflow path width control 107b, to bury the opening having the width W1, with a width W2 greater than the width W1 for controlling an optical mode. The ridge width W2 determines a dimension of an optical mode. The ridge 113a is formed of a p-semiconductor layer, for example, a p-InP layer. The ridge 113a is formed with a thickness of about 1.5 μm.

An electrode contact layer pattern 115a is formed on the ridge 113a. The electrode contact layer pattern 115a is formed of an InGaAs layer. The electrode contact layer pattern 115a is formed with a thickness of 0.3 μm.

A passivation layer 117 is formed on both sidewalls of the ridge 113a and on the etch stop layer pattern 105a. The passivation layer 117 is formed of an SOG (spin-on-glass) or polyimide. An electrode metal layer 119 is formed on the electrode contact layer pattern 115a and the passivation layer 117.

The ridge-type semiconductor laser of the present invention controls a current inflow path, using the width W1 of the opening formed inside the pattern for current inflow path width control 107b, and controls an optical mode using the ridge width W2 thereby maximably coinciding the respective space distributions of a current and an optical mode. Therefore, the ridge-type semiconductor laser of the present invention can reduce a threshold current, for example, as one of the characteristics of a laser. In the embodiment, the current inflow path width W1 is 1 μm, and the ridge width W2 is 3 μm.

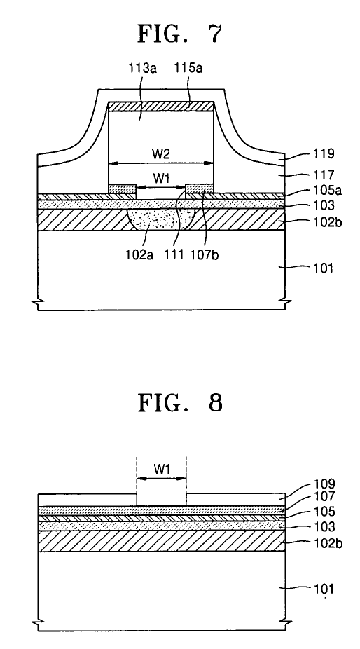

FIG. 7 is a sectional view of a ridge-type semiconductor laser according to another embodiment of the present invention.

In specific, like reference numerals of FIG. 7 refer to like elements of FIG. 6. The ridge-type semiconductor laser of FIG. 7 is the same as that of FIG. 6, just except that the active layer 102 is formed to be separated into a p-active layer 102a and an n-active layer 102b. The p-active layer 102a is formed under the ridge 113a, and other portion is formed of the n-active layer 102b. The p-active layer 102a is formed of a p-InGaAsP layer, and the n-active layer 102b is formed of an n-InGaAsP layer. The p-active layer 102a is formed by forming the n-active layer 102b on the substrate, and diffusing p-dopants during the growth of p-clad layer 103. Therefore, the ridge-type semiconductor laser of FIG. 7 can improve the laser characteristics since the p-n junction formed inside the active layer 102 stops the diffusion of holes during the operation.

FIGS. 8 through 11 are sectional views illustrating a method of fabricating the ridge-type semiconductor laser of FIG. 6.

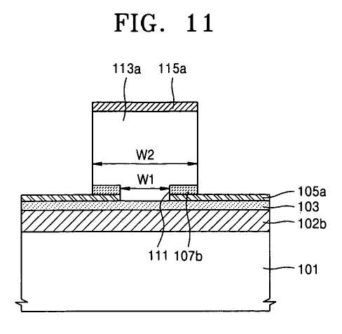

Referring to FIG. 8, an active layer 102 and a p-clad layer 103 are formed on an n-substrate 101. The n-substrate 101 uses an n-InP substrate, and the active layer 102 uses an InGaAsP layer with a quantum well structure or an InGaAsP layer with a non-quantum well structure. The p-clad layer 103 uses a p-InP layer. The p-clad layer 103 is formed with a thickness of 0.1 μm. In this embodiment, the p-clad layer 103 is formed to facilitate easy performance of a post-process, that is, a process of forming a p-semiconductor layer 113 (FIG. 10) using a MOCVD (metal organic chemical vapor deposition) method, but may not be formed.

An etch stop layer 105 is formed on the p-clad layer 103. The etch stop layer 105 is formed of an InGaAsP layer. The etch stop layer 105 is formed with a thickness of 300′.

An n-semiconductor layer 107 for controlling a current inflow path width is formed on the etch stop layer 105. The n-semiconductor layer 107 is formed of an n-InP layer. The n-semiconductor layer 107 is formed with a thickness of 0.2 μm.

A mask layer 109 is formed on the n-semiconductor layer 107 using a photolithography process, and the mask layer 109 opens the central portion of the n-semiconductor layer 107 as much as a width W1. The mask layer 109 is formed of a silicon nitride layer or a silicon oxide layer. The mask layer 109 is formed by forming a silicon nitride layer or a silicon oxide layer on the n-semiconductor layer 107, and etching the layer as much as a predetermined width W1 using a photolithography process. The width W1 is the current inflow path width.

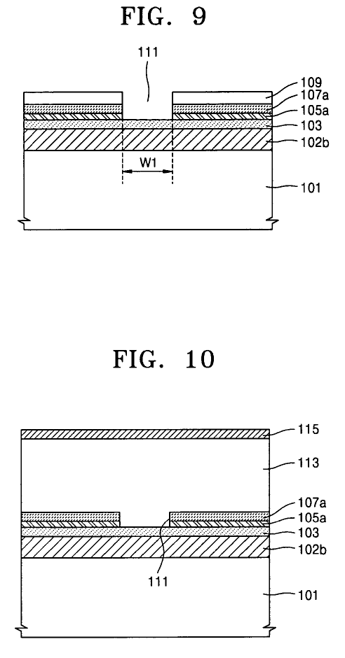

Referring to FIG. 9, using the mask layer 109 as an etch mask, the n-semiconductor layer 107 is etched using an etchant, for example, a mixture of HCl and H₃PO₄, thereby forming an n-semiconductor layer pattern 107a. Then, the etch stop layer 105 is etched using the mask layer 109 as an etch mask, and using an etchant, for example, a mixture of H₂SO₄, H₂O₂, and H₂O, thereby forming an etch stop layer pattern 105a. Thus, an opening 111 is formed inside the n-semiconductor layer pattern 107a and the etch stop layer pattern 105a with a width W1.

Referring to FIG. 10, the mask layer 109 used as the etch mask is removed. Then, a p-semiconductor layer 113 to be a ridge later is formed on the n-semiconductor layer pattern 107a while burying the opening 111. The p-semiconductor layer 113 uses a p-InP layer. The p-semiconductor layer 113 is formed with a thickness of about 1.5 μm. The p-semiconductor layer 113 is formed using a MOCVD (metal organic chemical vapor deposition) method. An electrode contact layer 115 is formed on the p-semiconductor layer 113. The electrode contact layer 115 uses an InGaAs layer. The electrode contact layer 115 is formed with a thickness of 0.3 μm.

Referring to FIG. 11, the electrode contact layer 115, the p-semiconductor layer 113, and the n-semiconductor layer pattern 107a are patterned by a photolithography and etching processes, thereby forming an electrode contact layer pattern 115a, a ridge 113a with a width W2 and a pattern for current inflow path width control 107b having an opening with a width W1.

Then, as shown in FIG. 4, a passivation layer 117 is formed on both sidewalls of the ridge 113a and on the etch stop layer pattern 105a. The passivation layer 117 is formed of SOG (spin-on-glass) or polyimide. An electrode metal layer 119 is formed on the electrode contact layer pattern 115a and the passivation layer 117. As such, in the ridge-type semiconductor layer of the present invention, the ridge width W2 and the current inflow path width W1 can be freely controlled by a photolithography process, thereby reducing a threshold current.

As described above, the present invention provides an advantage of improving the characteristics of the ridge-type semiconductor laser by separately controlling the extent that current is spread in the space, and the extent that optical mode is spread in the space, thereby to maximize the coincidence of the respective space distributions of current and optical mode.

That is, according to the present invention, the coincidence of the respective space distributions of the current and the optical mode can be maximized by controlling the current spread using the pattern for current inflow path width control having an opening with a width W1, and by controlling the dimension of the optical mode in the space only by the ridge width, thereby improving the characteristics of the semiconductor laser, for example, lowering the threshold current.

Further, the method of fabricating a ridge-type semiconductor laser according to the present invention can use the conventional fabrication method thereof, and reduces a threshold current as characteristics of the semiconductor laser.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A ridge-type semiconductor laser comprising:
an active layer formed on a substrate;
a pattern for a current inflow path control formed on the active layer and having an opening thereinside controlling a current inflow path with a width W1;
a ridge formed on the pattern for a current inflow path control with a width W2 greater than W1, and burying the opening with a width W1 and controlling an optical mode;
an electrode contact layer pattern formed on the ridge;
a passivation layer formed on both sidewalls of the ridge and on the active layer; and
an electrode metal layer formed on the electrode contact layer pattern and the passivation layer.

2. The ridge-type semiconductor laser of claim 1, wherein the substrate is formed of an n-substrate, the ridge is formed of a p-semiconductor layer, and the pattern for a current inflow path control is formed of an n-semiconductor layer.

3. The ridge-type semiconductor laser of claim 2, wherein the ridge is formed of a p-InP layer, the pattern for a current inflow path control is formed of an n-InP layer, and the active layer is formed of an InGaAsP layer with a quantum well structure or an InGaAsP layer with a non-quantum well structure.

4. The ridge-type semiconductor laser of claim 3, wherein the active layer under the ridge is formed of a p-InGaAsP layer, and the active layer other than that is formed of an n-InGaAsP layer.

5. The ridge-type semiconductor laser of claim 1, wherein a p-clad layer is further formed on the active layer.

6. A method of fabricating a ridge-type semiconductor laser comprising:
forming an active layer on an n-substrate;
forming an etch stop layer on the active layer;
forming an n-semiconductor layer on the etch stop layer;
patterning the n-semiconductor layer and the etch stop layer, thereby forming an n-semiconductor layer pattern having an opening thereinside with a width W1, and an etch-stop layer pattern;
forming a p-semiconductor layer burying the opening and formed on the n-semiconductor layer pattern;
forming an electrode contact layer on the p-semiconductor layer;
patterning the electrode contact layer, the p-semiconductor layer, and the n-semiconductor layer, thereby forming an electrode contact layer pattern, a ridge with a width W2 greater than the width W1, and a pattern for a current inflow path width control having an opening thereinside with a width W1;
forming a passivation layer on both sidewalls of the ridge and the etch stop layer pattern; and
forming an electrode metal layer on the electrode contact layer pattern and the passivation layer.

7. The method of claim 6, wherein the ridge is formed of a p-InP layer, the pattern for current inflow path control is formed of an n-InP layer, and the active layer is formed of an InGaAsP layer.

8. The method of claim 6, wherein the active layer under the ridge is formed of a p-InGaAsP layer, and the active layer other than that is formed of an n-InGaAsP layer.

9. The method of claim 6, wherein a p-clad layer is further formed on the active layer.

10. The method of claim 6, wherein the etch stop layer is formed of an InGaAsP layer.
